(19) United States
(12) Patent Application Publication
(10) Pub. No.: US 2020/0160018 A1
(43) Pub. Date: May 21, 2020

(54) ULTRASONIC BIOMETRIC SENSOR WITH TRANSMIT AND RECEIVE SIDE BEAMFORMING

(71) Applicant: QUALCOMM Incorporated, San Diego, CA (US)

(72) Inventors: Hrishikesh Panchawagh, Cupertino, CA (US); Kostadin Djordjev, Los Gatos, CA (US)

(21) Appl. No.: 16/197,494

(22) Filed: Nov. 21, 2018

(51) Int. Cl. G06K 9/00; H01L 41/08; H01L 27/20; H01L 41/25; H01L 41/113; B06B 1/06

(52) U.S. Cl. CPC G06K 9/0002; H01L 41/0825; H01L 27/20; B06B 2201/55; H01L 41/1134; B06B 1/0607; H01L 41/25

(57) ABSTRACT

The described architecture and techniques may provide for ultrasonic sensing using transmit and receive beamforming using an ultrasonic sensor with a continuous (e.g., non-segmented) blanket layer of piezo-sensitive material between a common electrode and an array of electrodes. For example, an ultrasonic biometric sensor may utilize a continuous blanket layer of piezo-sensitive material (e.g., such as a continuous copolymer, in lieu of an array of piezoelectric elements) between a common electrode and an electrode array for transmit and receive beamforming. The electrode array may employ individual transmission cycle control for each electrode to perform aspects of ultrasonic transmit and receive beamforming for biometric sensing/imaging. The continuous copolymer (e.g., or other blanket layer of piezo-sensitive material) may provide for a thin layer, between the common electrode and the electrode array, with desirable material properties to isolate each pixel from neighboring pixels and enable effective ultrasonic transmit and receive beamforming.

### BACKGROUND

The following relates generally to object scanning, and more specifically to ultrasonic biometric sensing with transmit and receive side beamforming.

Authentication data (e.g., such as usernames, passwords, biometric traits, etc.) is being increasingly used to control access to resources (e.g., such as computer and email accounts, mobile device access, etc.) and to prevent unauthorized access to important information or data stored in such accounts or devices. In some cases, biometric authentication techniques may provide for robust security due to, for example, the inherent universality, uniqueness, and permanence of certain biometric traits.

For example, in some cases, a device (e.g., computer, mobile device, etc.) or doorway (e.g., a lock safe or entryway into a private infrastructure) may utilize biometric authentication techniques for user access. In the context of an ultrasonic fingerprint imager, an ultrasonic wave may travel through a surface or platen on which a person's finger may be placed to obtain a fingerprint image. After passing through the platen, some portions of the ultrasonic wave encounter skin that is in contact with the platen (e.g., fingerprint ridges), while other portions of the ultrasonic wave encounter air (e.g., valleys between adjacent ridges of a fingerprint) and may be reflected with different intensities back towards the ultrasonic sensor. The reflected signals associated with the finger may be processed and converted to a digital value representing the signal strength of the reflected signal. When multiple reflected signals are collected over a distributed area, the digital values of such signals may be used to produce a graphical display of the signal strength over the distributed area (e.g., by converting the digital values to an image), thereby producing an image of the fingerprint. Thus, an ultrasonic sensor system may be used as a fingerprint sensor or other type of biometric sensor (e.g., in some implementations, the detected signal strength may be mapped into a contour map of the finger that is representative of the depth of the ridge structure detail).

In some cases, biometric sensors may further utilize transmit and receive beamforming techniques (e.g., for three dimensional (3D) or subdermal sensing and imaging). Ultrasonic biometric sensors capable of transmit and receive side beamforming, that may be efficiently manufactured, may be desired.

### SUMMARY

The described techniques relate to improved methods, systems, devices, and apparatuses that support ultrasonic biometric sensing with transmit and receive side beamforming. Generally, the described ultrasonic biometric sensor architecture may provide for biometric sensing via transmit and receive side beamforming, while facilitating device manufacturability. For example, in lieu of an array of micromachined piezoelectric elements, an ultrasonic biometric sensor may include a continuous blanket layer of piezo-sensitive material (e.g., such as a continuous copolymer) between an electrode array and a common electrode. The electrode array may employ individual transmission cycle control for each electrode to apply a voltage to various locations of the continuous piezoelectric layer. The electrode array and the common electrode may thus expand or contract the continuous layer at various locations, depending upon the transmission cycle for each electrode, thereby generating a beamformed signal (e.g., an ultrasonic beam that may be focused on a point or portion of an object). Returning waves or signals reflected off the portion of the object may then be received and processed for object sensing/imaging.

Techniques for biometric scanning utilizing such a device architecture is also described. For example, a device may include a continuous non-segmented blanket layer of copolymer between a common electrode (e.g., a top electrode, acoustic backer, etc.) and an electrode array. Each electrode of the electrode array may be individually controlled using some transmission cycle to create time delays (e.g., relative to transmission cycles of other electrodes of the electrode array) for transmit beamforming. The device may identify an ultrasonic signal transmission delay (e.g., a time delay or transmission cycle) for each electrode of the electrode array. In some cases, the time delays may be determined based on the material properties of the continuous piezoelectric layer (e.g., such as pixel isolation properties, acoustic properties, layer thickness, etc.), the portion of the object to be imaged, the spatial location of the portion on the platen, etc.

As such, the device may focus a beamformed ultrasonic signal on a portion of an object by transmitting (e.g., driving the electrode array) according to the identified ultrasonic signal transmission delays for each electrode of the electrode array. The ultrasonic signal may be transmitted based on the continuous piezoelectric layer (e.g., the continuous copolymer) between the common electrode and the electrode array (e.g., by applying voltage using the various electrodes of the array to contract or expand the piezoelectric layer to produce an ultrasonic beam focused on an object). The device may then receive a reflected wave (e.g., a portion of the transmitted beamformed ultrasonic signal that reflects off the portion of the object) using the electrode array. For example, the device may receive object reflected signals via a receive beam, by applying a time delay for each of the electrodes of the electrode array to receive the reflected wave. The device may then image the portion of the object (e.g., the portion of the object focused on by the transmitted beamformed signal) based on the received reflected wave.

A method of biometric scanning is described. The method may include identifying, for each of one or more electrodes of an electrode array, an ultrasonic signal transmission delay, and transmitting, based on a continuous piezoelectric layer, a beamformed ultrasonic signal based on the ultrasonic signal transmission delay for each of the one or more electrodes. The beamformed ultrasonic signal may be focused on a portion of an object. The method may further include receiving, using the electrode array, a reflected wave based on the transmitted beamformed ultrasonic signal, and imaging the portion of the object based on the reflected wave.

An apparatus for biometric scanning is described. The apparatus may include a processor, memory in electronic communication with the processor, and instructions stored in the memory. The instructions may be executable by the processor to cause the apparatus to identify, for each of one or more electrodes of an electrode array, an ultrasonic signal transmission delay, and transmit, based on a continuous piezoelectric layer, a beamformed ultrasonic signal based on the ultrasonic signal transmission delay for each of the one or more electrodes. The beamformed ultrasonic signal may be focused on a portion of an object. The instructions may be further executable by the processor to cause the apparatus to receive, using the electrode array, a reflected wave based on the transmitted beamformed ultrasonic signal, and image the portion of the object based on the reflected wave.

Another apparatus for biometric scanning is described. The apparatus may include means for identifying, for each of one or more electrodes of an electrode array, an ultrasonic signal transmission delay, transmitting, based on a continuous piezoelectric layer, a beamformed ultrasonic signal based on the ultrasonic signal transmission delay for each of the one or more electrodes, where the beamformed ultrasonic signal is focused on a portion of an object, receiving, using the electrode array, a reflected wave based on the transmitted beamformed ultrasonic signal, and imaging the portion of the object based on the reflected wave.

A non-transitory computer-readable medium storing code for biometric scanning is described. The code may include instructions executable by a processor to identify, for each of one or more electrodes of an electrode array, an ultrasonic signal transmission delay, transmit, based on a continuous piezoelectric layer, a beamformed ultrasonic signal based on the ultrasonic signal transmission delay for each of the one or more electrodes, where the beamformed ultrasonic signal is focused on a portion of an object, receive, using the electrode array, a reflected wave based on the transmitted beamformed ultrasonic signal, and image the portion of the object based on the reflected wave.

Some examples of the method, apparatuses, and non-transitory computer-readable medium described herein may further include operations, features, means, or instructions for identifying a transmission channel based on the continuous piezoelectric layer and the electrode array, and identifying the ultrasonic signal transmission delay for each of the one or more electrodes based on the identified transmission channel, where the beamformed ultrasonic signal may be transmitted based on the identified transmission channel and the identified ultrasonic signal transmission delay for each of the one or more electrodes. In some examples of the method, apparatuses, and non-transitory computer-readable medium described herein, the continuous piezoelectric layer includes a single continuous copolymer between the electrode array and a common electrode.

Some examples of the method, apparatuses, and non-transitory computer-readable medium described herein may further include operations, features, means, or instructions for scanning the beamformed ultrasonic signal portion by portion across the object, imaging each scanned portion of the object, combining each imaged portion of the object, and imaging the object based on the combining. Some examples of the method, apparatuses, and non-transitory computer-readable medium described herein may further include operations, features, means, or instructions for scanning the beamformed ultrasonic signal portion by portion across the object, identifying a receive beam using, for each of the one or more electrodes of an electrode array, a time delay for receiving one or more reflected waves based on the scanning, and sampling the one or more reflected waves based on the receive beam.

Some examples of the method, apparatuses, and non-transitory computer-readable medium described herein may further include operations, features, means, or instructions for scanning the receive beam portion by portion to image the object, and combining the results of the scanning to image the object. In some examples of the method, apparatuses, and non-transitory computer-readable medium described herein, combining the results of the scanning may include operations, features, means, or instructions for summing rows of the object scanned with the receive beam, and summing columns of the object scanned with the receive beam.

In some examples of the method, apparatuses, and non-transitory computer-readable medium described herein, the ultrasonic signal transmission delay for each of the one or more electrodes may be correlated with the one or more time delays for receiving the one or more reflected waves. Some examples of the method, apparatuses, and non-transitory computer-readable medium described herein may further include operations, features, means, or instructions for varying the ultrasonic signal transmission delay for each of the one or more electrodes to focus the beamformed ultrasonic signal at various depths of the object.

Some examples of the method, apparatuses, and non-transitory computer-readable medium described herein may further include operations, features, means, or instructions for identifying one or more transmission channels based on the electrode array and a number of ultrasonic transmission delays for transmitting the beamformed ultrasonic signal, and selecting a transmission channel of the one or more transmission channels based on the portion of the object, where the beamformed ultrasonic signal may be transmitted based on the selected transmission channel.

### BRIEF DESCRIPTION OF THE DRAWINGS

FIGS. 1A and 1B illustrate example systems for biometric scanning that support ultrasonic biometric sensing with transmit and receive side beamforming in accordance with aspects of the present disclosure.

FIG. 2 illustrates an example of a sensor architecture that supports ultrasonic biometric sensing with transmit and receive side beamforming in accordance with aspects of the present disclosure.

FIGS. 3A and 3B illustrate examples of a sensor configuration that support ultrasonic biometric sensing with transmit and receive side beamforming in accordance with aspects of the present disclosure.

FIGS. 4A and 4B illustrate example transmit/receive delay configurations that support ultrasonic biometric sensing with transmit and receive side beamforming in accordance with aspects of the present disclosure.

FIG. 5 shows a block diagram of a device that supports ultrasonic biometric sensing with transmit and receive side beamforming in accordance with aspects of the present disclosure.

FIG. 6 shows a diagram of a system including a device that supports ultrasonic biometric sensing with transmit and receive side beamforming in accordance with aspects of the present disclosure.

FIGS. 7 and 8 show flowcharts illustrating methods that support ultrasonic biometric sensing with transmit and receive side beamforming in accordance with aspects of the present disclosure.

### DETAILED DESCRIPTION

In some ultrasonic sensor systems, an ultrasonic transmitter may be used to send an ultrasonic wave through an ultrasonically transmissive medium or media and towards an object to be detected. The transmitter may be operatively coupled with an ultrasonic sensor configured to detect portions of the ultrasonic wave that are reflected from the object. For example, an ultrasonic pulse may be produced by starting and stopping the transmitter during a very short interval of time. At each material interface encountered by the ultrasonic pulse, a portion of the ultrasonic pulse is reflected.

In the context of an ultrasonic fingerprint imager, the ultrasonic wave may travel through a surface or platen on which a person's finger may be placed to obtain a fingerprint image. After passing through the platen, some portions of the ultrasonic wave encounter skin that is in contact with the platen (e.g., fingerprint ridges), while other portions of the ultrasonic wave encounter air (e.g., valleys between adjacent ridges of a fingerprint) and may be reflected with different intensities back towards the ultrasonic sensor. The reflected signals associated with the finger may be processed and converted to a digital value representing the signal strength of the reflected signal. When multiple of such reflected signals are collected over a distributed area, the digital values of the reflected signals may be used to produce a graphical display of the signal strength over the distributed area (e.g., by converting the digital values to an image), thereby producing an image of the fingerprint. Thus, an ultrasonic sensor system may be used as a fingerprint sensor or other type of biometric sensor. In some implementations, the detected signal strength may be mapped into a contour map of the finger that is representative of the depth of the ridge structure detail.

In some cases, ultrasonic sensors may use a plane transmit wave by applying a uniform signal across the active area (e.g., the electrode or electrode array) of the sensor. The object (e.g., fingerprint, eye, face, etc.) image may then be created by deconvolution of several frames captured at different time delays. In some cases, such techniques may be limited to two dimensional (2D) imaging and may use several captured frames for deconvolution. As such, some ultrasonic sensors may employ transmit and receive beamforming techniques. For example, an ultrasonic sensor may utilize a phased array of transduce elements, where individual transducers of the phased array are designed to work independently. Individual transducers may drive transmit waveforms according to predetermined time delays (e.g., relative to transmit waveforms driven by other individual transducers) to focus energy on a location (e.g., portion) of an object. The reflected wave (e.g., the signal reflected from the object) may then be detected by the same transducer array with a predetermined time delay in the reverse order. The signals received by the phased array may be combined and to give a focused region of the image. Beneficially, ultrasonic sensors utilizing such transmit and receive beamforming may alleviate the need for special deconvolution by capturing separate frames, and may be less dependent on acoustic resonance. Further such sensors may provide for wider up design space, operation at higher drive frequencies giving higher resolution, the ability to image inside an object (e.g., such as sub-dermal layers, blood vessels etc.), etc.

However, ultrasonic sensors utilizing a phased array of transduce elements (e.g., such as sensors utilizing piezoelectric micromachined ultrasonic transducer (PMUT) arrays or other microelectromechanical (MEM) array sensors) may be difficult and/or costly to manufacture. That is, conventional ultrasonic sensors that support transmit and receive beamforming may utilize piezoelectric elements formed into an array (e.g., piezoelectric elements may be diced, assorted, and filled with some other material in between) or transducers manufactured with cavities (e.g., such as Aluminum Nitride implementations), and may be difficult or costly to manufacture.

The described architecture and techniques may provide for ultrasonic sensing using transmit and receive beamforming via an ultrasonic sensor with a continuous blanket layer of piezo-sensitive material between an array of electrodes and a common electrode. For example, in lieu of an array of piezoelectric elements, an ultrasonic biometric sensor may include a continuous (e.g., non-segmented) blanket layer of piezo-sensitive material (e.g., such as a continuous copolymer) between an electrode array and a common electrode. The electrode array may employ individual transmission cycle control for each electrode to perform aspects of ultrasonic transmit and receive beamforming for biometric sensing/imaging. The continuous copolymer (e.g., or other blanket layer of piezo-sensitive material) may provide for a thin layer, between the electrode array and the common electrode, with desirable material properties to isolate each pixel from neighboring pixels and enable effective ultrasonic transmit and receive beamforming. Such an architecture may provide for more efficient (e.g., less costly) manufacturability of ultrasonic sensors with transmit and receive beamforming capability.

Aspects of the disclosure are initially described in the context of a system for object scanning. Example sensor architecture and example sensor configurations are then described. Aspects of the disclosure are further illustrated by and described with reference to apparatus diagrams, system diagrams, and flowcharts that relate to ultrasonic biometric sensing with transmit and receive side beamforming.

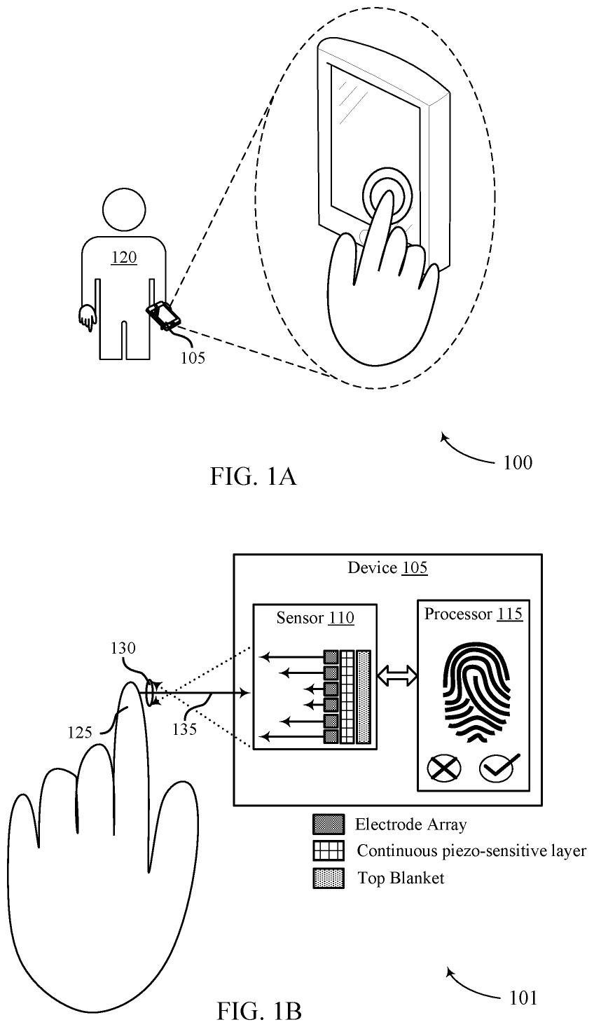

FIG. 1A illustrates an example of a system 100 that supports ultrasonic biometric sensing with transmit and receive side beamforming in accordance with aspects of the present disclosure. System 100 may include a user 120 and a device 105, where the device 105 may employ object sensing techniques. For example, device 105 may employ biometric authentication techniques (e.g., ultrasonic biometric scanning and biometric trait authentication processing) for user 120 access. FIG. 1B illustrates an example of a system 101 that supports ultrasonic biometric sensing with transmit and receive side beamforming in accordance with aspects of the present disclosure. In some cases, system 101 may illustrate an enlarged perspective of system 100. For example, system 101 may include an object 125 (e.g., which in some cases may be a finger or finger print of user 120) and device 105, and may illustrate device 105 implementing biometric authentication techniques described herein via sensor 110 and processor 115 components of the device 105.

Techniques described with reference to aspects of system 100 and/or system 101 are done so for exemplary purposes only, and are not intended to be limiting in terms of the applicability of the described techniques. That is, the techniques described may be implemented in, or applicable to, other examples of object scanning or object sensing by analogy, without departing from the scope of the present disclosure. For example, the described ultrasonic biometric sensor and associated biometric sensing techniques may be applied for scanning of other biometric traits (e.g., such as an eyeball or retina, a face, etc.), and may be applied to other authentication environments (e.g., such as computer security, doorway or infrastructure access, medical record examination, etc.).

Device 105 may include a continuous (e.g., non-segmented) blanket layer of piezo-sensitive material (e.g., such as a continuous copolymer) between an electrode array and a common electrode (e.g., which may be referred to as a top blanket electrode, a reference electrode, etc.). The electrode array may employ individual transmission cycle control for each electrode to perform aspects of ultrasonic transmit and receive beamforming for biometric sensing/imaging. That is, the electrode array may include several electrodes that may each be associated (e.g., connected to) a transmit circuit and a receive circuit, where delays may be applied to each electrode or to selected groups of electrodes for transmit and receive beamforming.

For example, in some cases, the device 105 may include an array of pixel circuits disposed on a substrate (e.g., which may be referred to as a backplane). In some implementations, each pixel circuit may include one or more thin film transistor (TFT) elements, electrical interconnect traces and, in some implementations, one or more additional circuit elements such as diodes, capacitors, and the like. Each pixel circuit may include a pixel input electrode (e.g., that electrically couples the piezoelectric layer to the pixel circuit).

Each transmit circuit associated with an electrode of the electrode array may be driven with a transmission cycle (e.g., associated with some transmit delay) such that a voltage may be applied to contract and expand different portions of the continuous piezoelectric layer to convert electrical energy into mechanical energy (e.g., into a beamformed ultrasonic signal). As such, the sensor 110 may transmit a beamformed ultrasonic signal 130 focused on a portion of an object 125, based on the driving of the electrode array.

The ultrasonic signal may interact with the object 125 such that a reflected signal 135 may then be measured by the sensor 110. Some portions of the ultrasonic wave encounter skin that is in contact with the platen (e.g., fingerprint ridges), while other portions of the ultrasonic wave encounter air (e.g., valleys between adjacent ridges of a fingerprint), and may be reflected with different intensities back towards the ultrasonic sensor 110. Each pixel circuit may be configured to convert an electric charge generated in the piezoelectric receiver layer (e.g., from the reflected ultrasonic signal 135) proximate to the pixel circuit into an electrical signal. For example, localized charges may be collected by the pixel input electrodes and passed on to the underlying pixel circuits. The charges may then be amplified by the pixel circuits and provided to the control electronics, which processes the output signals. Reflected signals 135 associated with the object 125 may thus be processed by a processor 115 and converted to a digital value representing the signal strength of the reflected signal. When multiple such reflected signals 135 are collected over a distributed area, the digital values of such signals may be used to produce a graphical display of the signal strength over the distributed area. For example, the processor 115 may convert the digital values to an image, thereby producing an image of the object 125. In some cases, the processor 115 may further compare the produced image to a stored image for authentication decisions.

For example, each pixel of a pixel array may be associated with a local region of the continuous piezo-sensitive layer, and may include or be associated with a peak detection diode and a readout transistor (e.g., these elements may be formed on or in the backplane to form the pixel circuit). In practice, the local region of piezoelectric sensor material of each pixel may transduce received ultrasonic energy into electrical charges. The peak detection diode may register the maximum amount of charge detected by the local region of piezoelectric sensor material. Each row of the pixel array may then be scanned (e.g., through a row select mechanism, a gate driver, or a shift register) and the readout transistor for each column may be triggered to allow the magnitude of the peak charge for each pixel to be read by additional circuitry (e.g., a multiplexer, an analog to digital converter, etc.). The pixel circuit may include one or more TFTs to allow gating, addressing, and resetting of the pixel. Each pixel circuit may provide information about a small portion of the object detected by the ultrasonic sensor system. In some cases, the detection area of the ultrasonic sensor system may be selected depending on the intended object of detection. For example, the detection area may range from about 5 mm×5 mm for a single finger to about 3 inches×3 inches for four fingers. Smaller and larger areas, including square, rectangular and non-rectangular geometries, may be used as appropriate for depending on the object 125.

The continuous copolymer (e.g., or other blanket layer of piezo-sensitive material) may provide for a thin layer, between the common electrode and the electrode array, with desirable material properties to isolate each pixel from neighboring pixels and enable effective ultrasonic transmit and receive beamforming. Such an architecture (e.g., which may be simplified compared to conventional architectures implementing MEM system arrays, PMUT arrays, cavity based piezoelectric layers, etc.) may provide for more efficient (e.g., less costly) manufacturability of ultrasonic sensors with transmit and receive beamforming capability.

As used herein, a device 105 may also be referred to as a mobile device, a wireless device, a remote device, a handheld device, a subscriber device, an authentication device, a biometric sensing device, a scanning device, or some other suitable terminology. A device 105 may also be a personal electronic device such as a cellular phone, a personal digital assistant (PDA), a tablet computer, a laptop computer, a personal computer, a display device (e.g., any device with a display or screen), an entry way system, a security lock, etc. In some examples, a device 105 may also refer to an Internet of Things (IoT) device, an Internet of Everything (IoE) device, a machine type communication (MTC) device, a peer-to-peer (P2P) device, or the like, which may be implemented in various articles such as appliances, vehicles, meters, or the like. Further examples of devices that may implement one or more aspects of ultrasonic biometric sensors and associated techniques may include Bluetooth devices, personal data assistants (PDAs), wireless electronic mail receivers, hand-held or portable computers, netbooks, notebooks, smartbooks, tablets, printers, copiers, scanners, cash machines, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (including odometer and speedometer displays, etc.), cockpit controls and/or displays, camera view displays (such as the display of a rear view camera in a vehicle), electronic photographs, electronic billboards or signs, and projectors.

Any of such devices may include a sensor 110 (e.g., which may be referred to as a biometric sensor, and electrode array, a scanner, etc.) that outputs a signal or imaging information indicative of traits (e.g., biometric traits) associated with object 125. In response to that signal, the processor 115 may image the object 125, perform an authentication analysis, etc. In some cases, the sensor 110 may be attached to or mounted on a frame of the device 105 near or under a cover surface of the device's display (e.g., an organic light emitting diode (OLED) display, plastic OLED (pOLED) display, etc.). Further, the device 105 may include electrical connections associated with the sensor 110 and the processor 115. In some examples, a general processor of the device 105 may perform aspects of the processor 115.

The processor 115 may receive the signal representative of object 125 imaging information, and may process such information as discussed in more detail above (e.g., the processor 115 may image object 125, perform authentication procedures, etc.). In some cases, the processor 115 and/or sensor 110 may introduce an applied voltage that may drive one or more electrodes of the sensor 110 to transmit a beamformed ultrasonic signal 130 (e.g., to focus beam onto a point or portion of object 125). In some other cases, the processor 115 and/or sensor 110 may apply bias voltages to one or more electrodes of the sensor 110 to receive a reflected signal 135 (e.g., to focus a receive beam according to the focused beamformed ultrasonic signal 130, the used transmission delays or transmission cycle, the expected reflected signal 135, etc.).

In some cases, a device 105 may include a sensor controller or control unit that is configured to control various aspects of the sensor system, e.g., ultrasonic transmitter timing and excitation waveforms, bias voltages for the ultrasonic receiver and pixel circuitry, pixel addressing, signal filtering and conversion, readout frame rates, and so forth. The sensor controller may also include a data processor (e.g., processor 115) that receives data from the ultrasonic sensor circuit pixel array. The data processor may translate the digitized data into image data of the object 125 or format the data for further processing (e.g., such as for authentication procedures).

For example, the control unit or processor 115 may send a transmitter (Tx) excitation signal to a Tx driver of each electrode (e.g., or a channel of electrodes) to cause the Tx driver to excite the ultrasonic transmitter and produce ultrasonic waves or signals. The control unit or processor 115 may send level select input signals through a receiver (Rx) bias driver to bias the receiver bias electrode and allow gating of acoustic signal detection by the pixel circuitry. A demultiplexer may be used to turn on and off gate drivers that cause a particular row or column of sensor pixel circuits to provide sensor output signals. Output signals from the pixels may be sent through a charge amplifier, a filter such as an RC filter or an anti-aliasing filter, and a digitizer to the data processor. In some cases, portions of the system may be included on the TFT backplane and other portions may be included in an associated integrated circuit.

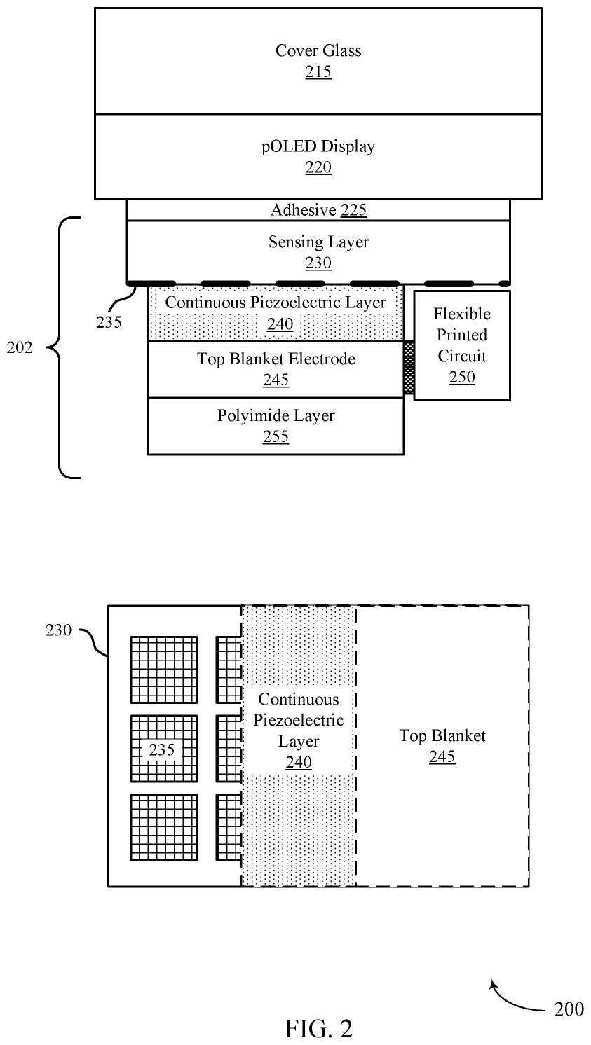

FIG. 2 illustrates an example of a sensor architecture 200 that supports ultrasonic biometric sensing with transmit and receive side beamforming in accordance with aspects of the present disclosure. In some examples, sensor architecture 200 may implement aspects of system 100 and/or system 101. A sensor architecture 200 may include a cover glass 215, a pOLED display 220, and a sensor 202. A sensor 202 may include a sensing layer 230, a Transmit/Receive electrode array 235, a continuous piezo electric layer 240, a top blanket electrode 245, a functional layer (e.g., polyimide layer 255), and a flexible printed circuit (FPC) 250. Additionally, sensor architecture 200 may have touch interface functionality. In some cases, some elements of sensor architecture 200 may be removed or replaced (e.g., by similar or otherwise suitable elements). In some cases, additional elements may be added to sensor architecture 200. Further, in some cases, elements of sensor architecture 200 may be rearranged or reordered (e.g., the disclosure is not limited to the illustrated arrangement, as the sensor 202 may be flipped upside down within sensor architecture 200 and still maintain functionality).

The cover glass 215 may refer to any display cover material, with examples including plastic, ceramic, sapphire, glass, etc. In some implementations, the cover glass 215 may be a cover plate, such as a cover plastic or a lens plastic for a pOLED display 220 of a display device (e.g., mobile device, tablet, etc.). For example, an object, such as a portion of a hand, finger, palm, etc., may be placed upon the cover glass 215, and object detection and imaging may be performed through the cover glass 215. In some cases, the cover glass 215 may include one or more polymers, such as one or more types of parylene for applications in which a thin layer is desired. In some implementations, the cover glass 215 may be placed over and coupled with a pOLED display 220 as a protective layer. In some implementations the cover glass 215 may extend beyond the span of the pOLED display 220 or vice versa. In other cases, the cover glass 215 and the pOLED display 220 may span the same area.

A pOLED display 220 may refer to a display module or a visual display included underneath cover glass 215. A pOLED display 220 may be attached to a sensor 202 by an adhesive 225 (e.g., a thermally cured epoxy, a UV-curable epoxy etc.). In some cases, the sensor 202 may include the adhesive 225. In some cases, the cover glass 215, and the pOLED display may extend beyond the span of the sensor 202. In other cases, the sensor 202 may span the area of the pOLED display 220 and the cover glass 215. In some examples, the sensor 202 may be configured to transmit ultrasonic waves and to receive ultrasonic sensor signals corresponding to ultrasonic waves reflected from an object (e.g., finger) in contact with the cover glass 215.

The sensor 202 may include a sensing laying 230, an electrode array 235, a continuous piezoelectric layer 240, a top blanket electrode 245, and an FPC 250. In some cases, a sensor 202 may include a polyimide layer 255. Different implementations may use different materials for the sensing layer 230. In some cases, a sensing layer 230 may be a silicon substrate, a TFT substrate, etc. A sensing layer 230 may have an array of ultrasonic transmitting and receiving pixels associated with the layer. Ultrasonic waves may be transmitted, by the electrode array 235, through the sensor stack and towards an overlying object. The various layers of the sensor stack may, in some examples, include one or more substrates of glass or other material (such as plastic or sapphire). In some cases, the sensor stack may include a substrate to which a light source system (not shown) may be coupled, which may be a backlight of a display according to some implementations. In alternative implementations, a light source system may be coupled to a front light. Accordingly, in some implementations a light source system may be configured for illuminating a display and the target object.

In some cases, a sensor 202 may include a transmit/receive electrode array 235 that may include of an array of pixels with transmit and receive drive circuitry and timing controls. Pixels may be grouped into a super-pixel with a predefined size and aperture. In some cases, transmit/receive electrode array 235 (e.g., which may drive and sense ultrasonic signals) may refer to pixel electrodes each associated with a pixel of the pixel array. In some cases, the electrode array 235 may refer to a transceiver array, or to pixel array, pixel circuitry, and corresponding pixel electrodes. A focused ultrasonic signal may be transmitted by the transmit/receive electrode array 235 and may travel towards a finger (or other object to be detected), passing through at least the cover glass 215 and the pOLED display 220. A portion of the wave not absorbed by the object to be detected may be reflected by the object. The reflected signal may pass back through the cover glass 215 and the pOLED display 220 and may be received by the sensor 202.

As described herein, sensor 202 may include a continuous piezoelectric layer 240. In some cases, the continuous piezoelectric layer 240 may be formed as a continuous layer on a surface of the sensing layer 230. Specific examples of piezoelectric materials that may be employed include ferroelectric polymers such as polyvinylidene fluoride (PVDF) and polyvinylidene fluoride-trifluoroethylene (PVDF-TrFE) copolymers. Examples of PVDF copolymers include 60:40 (molar percent) PVDF-TrFE, 70:30 PVDF-TrFE, 80:20 PVDFTrFE, and 90:10 PVDR-TrFE. Other examples of piezoelectric materials that may be employed include polyvinylidene chloride (PVDC) homopolymers and copolymers, polytetrafluoroethylene (PTFE) homopolymers and copolymers, and diisopropylammonium bromide (DIPAB).

In some cases, the piezoelectric layer 240 material may be selected based at least in part on manufacturability considerations (e.g., such as material cost and availability), pixel isolation properties, properties of the electrode array 235 or sensor 202, etc. For example, a piezoelectric material may be selected based at least in part on its material properties effect on pixel isolation for certain electrode array size and spacing (e.g., sensor 202 configurations, such as sensor configurations with tightly spaced electrodes, may use copolymers associated with a greater degree of pixel isolation). In some cases, the continuous piezoelectric layer 240 may be selected based at least in part on acoustic properties of the selected material, as well as the dimensions and configuration of the electrode array (e.g., to support transmit/receive beamforming operations for the given electrode array configuration). The thickness of the continuous piezoelectric layer 240 may be selected so as to support the transmitting and receiving of ultrasonic waves.

Ultrasonic waves may be generated by applying a voltage to the continuous piezoelectric layer 240 to expand or contract the layer depending upon the signal applied, thereby generating a signal. A voltage may be applied to the continuous piezoelectric layer 240 via a transmit/receive electrode array 235. In this fashion, an ultrasonic signal may be made by changing the thickness of the layer via a piezoelectric effect (e.g., acoustic wave or acoustic wave elements may propagate from various locations of the continuous piezoelectric layer according to various applied voltage across different locations of the layer, resulting or cumulating in a focused ultrasonic wave transmission). Example frequencies of the ultrasonic waves may be in the range of 5 MHz to 30 MHz, with wavelengths on the order of a millimeter or less.

In some cases, a top blanket electrode 245 may be positioned in between the continuous piezoelectric layer 240 and another layer (e.g., polyimide layer 255). The Top Blanket Electrode 245 may be coupled to (e.g., through the FPC 250) one or more sensor controller(s) or other circuitry (e.g., a control unit, control circuitry or an applications processor) for signal processing of signals to/from the sensor 202.

An FPC 250 may be included in a sensor architecture 200 and may be coupled to a top blanket electrode 245. The FPC 250 may include one or more dielectric layers and interconnects (e.g., traces, vertical interconnect access (VIAs), and pads). In some implementations, the FPC 250 may be electrically coupled to a sensor controller or other circuitry (e.g., a control unit, control circuitry or an applications processor) for signal processing of signals to/from the sensor 202. In some implementations, the FPC 250 may include other functionality, such as one or more capacitive touch electrodes for low-power wakeup, menu selection and navigation functionality.

In some examples, a sensor 202 may include a polyimide (PI) layer 255 (e.g., a cap, protective layer, conductive layer, adhesive layer, substrate layer, etc.). In some cases, the polyimide layer 255 may be coupled to top blanket electrode 245. In some cases, an alternate layer may be used in a similar fashion, or no such layer may be implemented in the architecture.

As such, sensor architecture 200 may provide an ultrasonic sensor with a continuous piezo-sensitive layer (e.g., continuous piezoelectric layer 240) in lieu of micromachined piezoelectric elements (e.g., such as PMUT arrays, MEM piezo arrays, cavity based piezoelectric layers, etc.). The sensor architecture 200 may effectively enable a phased array of transduce elements based on the material properties of the continuous piezo-sensitive layer or copolymer (e.g., as the copolymer may isolate pixels and corresponding local regions of the copolymer from voltages applied by neighboring pixels of the pixel array). As such, individual transducers of a phased array may be designed to work independently and driven with transmit waveforms with predetermined time delays to focus energy on a portion of an object (e.g., like a finger surface or inside of a finger). As such, a phased array of transducer elements with tight pixel spacing (e.g., 500 pixels per inch (ppi)) may be attainable with the described copolymer process (e.g., the pixel array may act as a phase array without segmentation of the piezoelectric layer).

The present disclosure describes architecture for improved biometric sensing capabilities over existing architecture. It provides systems, methods and techniques by which an ultrasonic biometric sensor architecture (e.g., fingerprint sensor, finger touch sensor, heart rate sensor, blood flow sensor, etc.) using transmit and receive side beamforming with a continuous piezoelectric layer may be used as an effective solution for low-cost, highly-manufacturable, under-display authentication. A piezo-sensitive element (e.g., polymer, copolymer, etc.) may be formed as a continuous layer on a surface of the sensing layer, which may eliminate the need for segmented elements (e.g., segmented micromachined elements) as found in some examples of biometric sensor (e.g., which may provide for more efficient and cost-effective manufacturability).

In some examples of the implementation of the sensor architecture, both transmitting and receiving pixels may be used to form an ultrasonic beam and act as a phased array. The phased array may be formed by grouping multiple pixels into a super-pixel with a predefined size and aperture. Individual transducers of the phased array may work independently and may be driven by transmit waveforms with predetermined transmit time delays to focus an ultrasonic beam within the top imaging surface. The focused transmission beam may then scan point by point to sample the object from the top surface. The transducer array may then sample the returning ultrasonic signal with a predefined delay within the super-pixel. The received signals from all pixels in the super-pixel may be combined as a single readout. The focused receiving beam may then scan point by point to generate an image.

A super-pixel may refer to a plurality of pixels. In some cases, a super-pixel may include a single center pixel and one or more rings of pixels that surround the center pixel, and each pixel in a ring of pixels may have a substantially equal distance from the center pixel. In other cases, a super-pixel may include a grid (e.g., a 2×2 grid, a 4×4 grid, etc.) of pixels. By appropriately applying phase/time delays to each respective pixel or pixel set within the super-pixel, time of flight and constructive interference between ultrasonic emissions from each group or channel within the super-pixel may result in a focused, shaped, and relatively high intensity ultrasonic signal. For example, each pixel set may be supplied with a transmission signal having a predetermined time delay. The time delay for each pixel set may be selected so that the acoustic pressure created by each super-pixel is focused at a predetermined location. For example, a super-pixel may correspond to four pixel sets, and ultrasonic emissions from the super-pixel may be focused by first applying an excitation signal to a fourth pixel set; following a time delay, applying the excitation signal to a third pixel set; following another time delay, applying the excitation signal to a second pixel set; and, following yet a further time delay, and applying excitation signal to the center pixel (or first pixel set).

Each pixel set may be systematically coupled with transceiver electronics, such that the pixel sets may be separately actuated with a transmission signal having a controllable phase and/or time delay. When plane wave excitation and transmission is desired, appropriate for fingerprint imaging, for example, this may be achieved by applying substantially the same delay to all groups of pixels (e.g., or electrodes) in the super-pixel. Alternatively, in a beam-focusing or transmit-side beamforming mode, the time delay for each respective pixel set may be selected so that the acoustic pressure created by each super-pixel (e.g., via the voltages applied to the continuous piezo-sensitive layer by each respective pixel set) is focused at a predetermined distance from the super-pixel center using beamforming principles.

As such, the continuous piezoelectric layer 240 (e.g., a continuous copolymer) may be implemented between the electrode array 235 and the top blanket electrode 245. Material properties of the continuous piezoelectric layer 240 may provide for pixel isolation, and thus transmit and receive beamforming capabilities (e.g., while providing for more cost friendly manufacturability compared to other ultrasonic sensors with transmit/receive beamform capabilities). For example, a continuous copolymer (e.g., or other non-segmented piezo-sensitive layer) may be implemented (e.g., depending on the copolymer used) to provide for pixel isolation such that each electrode, pixel, pixel group, channel, super-pixel, etc. may be isolated (e.g., from neighboring crosstalk issues). The acoustic properties and/or pixel isolation properties of the continuous piezoelectric layer 240 may thus provide for beamforming via the electrode independent transmission cycle control for electrodes of the electrode array.

An ultrasonic biometric sensor architecture 200 with transmit and beamforming capabilities may provide several potential advantages. Special deconvolution of separate captured frames may not be required in this system since the received signals may be combined into a single readout. In some examples, the sensor architecture 200 may be less dependent on acoustic resonance, therefore widening up design space. It may be able to operate at higher drive frequencies which in turn may equate to higher resolution imaging and the ability to image through pOLED displays. Sensor architecture 200 may support imaging of sub-dermal layers (e.g., tissue, blood vessels, finger veins, etc.) which may be a more fraud-resistant method of authentication than other methods of fingerprint scanning and may provide health monitoring services (e.g., heart rate sensing, blood flow sensing, etc.)

Sensor architecture 200 may include a phased array of transduce elements where individual transducers of the phased array are designed to work independently and are driven by transmit waveforms with predetermined time delays to focus energy on a signal location or object (e.g., a finger surface, finger insides, etc.). A reflected wave may be detected by the same transducer array with a predetermined time delay in reverse order. The signal received by the phased array may be combined to create an image focused region. Imaging capabilities may include 2D surface imaging and 3D fingerprint imaging including the imaging of subcutaneous layers and tissues as well as blood vessels. In some cases, the method may include support for transmit and receive side beamforming as well as a plane wave mode.

In some examples, a sensor architecture may be composed of several layers. Layers may include cover glass, a pOLED display, an adhesive layer, a silicon sensing layer, a transmit/receive electrode layer composed of a number of electrodes, a continuous piezoelectric layer (e.g., copolymer, polymer, other piezoelectric material), a top blanket (e.g., top electrode and acoustic backer) (e.g., copper, etc.) and a functional layer (e.g., polyimide, etc.). In some cases, the top electrode and acoustic backer layer may be connected to a flexible printed circuit. A flexible printed circuit may be used as an electrical connection technique and may be used to connect the various components of the sensor architecture as discussed with processors, drivers, and/or other control hardware. While FPCs may be useful for such connections other methods of electrical connection may be employed.

In some cases, a sensor architecture may have ultrasonic transmitting and receiving pixels that form a sensor pixel array. A sensor pixel array may have a transmit and receive drive circuitry, and timing controls. In some cases, a pixel array may have a pixel electrode (e.g., transmit/receive electrode) associated with each pixel in the array. The number of pixel electrodes may form the bottom electrodes of a transducer array. The bottom electrodes may be used to drive and sense ultrasonic signals.

In some examples, there may be a number of options for transmission side beamforming through sensor architecture design. One option may include a continuous un-patterned copolymer layer as a piezoelectric material deposited on top of the transmit/receive electrode (e.g., pixel electrode array). One option may include a blanket top electrode and acoustic backer deposited on top of the copolymer for use as a top electrode connected to a reference signal. A transmit or receive switch may be used to connect to either a transmit column driver (e.g., transmit pixel driver) or a receive pixel driver (e.g., a tx/rx switch may control the electrode array 235 to transmit circuitry or receive circuitry). Top blanket signals (e.g., top blanket electrode 245 control) with adjustable time delays may be utilized. In this case the receive electrodes may be positioned on top of a silicon layer.

In another option, a patterned top electrode (e.g., transmit drive columns electrodes) may be deposited on top of an un-patterned piezoelectric layer (e.g., copolymer, polymer, etc.) to form column transmit drivers capable of one-dimensional beamforming. In such an option top blanket signals may have adjustable time delays between columns before scanning. In this case the receive electrodes may be positioned between a silicon or TFT layer and the continuous piezoelectric layer.

In another option, a patterned top electrode (e.g., transmit drive electrodes), a patterned dielectric, and a patterned routing layer may be deposited on top of the unpatterned piezoelectric layer (e.g., copolymer, polymer, etc.). In such an option, top blanket signals may have adjustable time delays between columns before scanning. In such an example, the receive electrodes may be positioned between a silicon or thin film transistor layer and the piezoelectric layer.

In some examples, the sensor architecture may determine certain parameters and may define a tuning algorithm. In some cases, the aperture may refer to the size of the transmitting array in the sensor architecture. The aperture may be greater than or equal to the depth of focus. In cases where an asymmetric design may be implemented the number of transmit/receive channels may be a function of the aperture and the pitch:

$$N = \frac{Aperture - Pitch}{Pitch} ( \frac{1}{2} )$$

where the pitch is the space from the edge of one transducer element to the corresponding edge of an adjacent transducer element and is less than or equal to

$$\frac{λ}{2} ,$$

where λ may be related to the wavelength in the cover glass medium for a given ultrasonic frequency. In other cases where the aperture is about equal to the depth of focus, the channels, N, required may depend on the depth of focus, D, and the ultrasonic wavelength, λ, in the cover glass as follows:

$$N \geq \frac{\frac{2 D}{λ} - 1}{2}$$

In some cases, multiple pixels may be grouped into a super-pixel with a predetermined size and aperture. Super-pixels positioned in close proximity to each other may experience crosstalk. Crosstalk may be mitigated by a gap between super-pixels. In some cases, the gap between super-pixels may be approximately half of the wavelength in the cover glass

$$( e . g . , \frac{λ}{2} ) .$$

In some situations, pixels in a super-pixel may be missing (e.g., edges, sides, etc.) and the method may include ignoring the missing pixels and applying a similar method as applied to areas in which no pixels may be missing.

In some examples a sensor readout architecture allows for both plane wave transmitting and beamformed transmitting methods. A sensor readout architecture may support plane wave or beam formed receiving at the hardware. Delay and sum beamforming or peak detect and sum beamforming may be used as part of the method. Pixels in a sensor architecture may be capable of transmit beam forming by selecting transmit channels with specific transmit delays to focus the transmit beam. Pixels in an architecture may also be capable of receive beam forming by sampling at range gate delay (RGD) with specific receive delays for each pixel within a super-pixel. RGD and range gate window (RGW) time intervals may support delay and sum beamforming as a part of a receive sampling method. RGD may be determined by the time a maximum absolute receive signal is detected. RGW may be determined by the duration of the received signal.

For example, reflected acoustic waves (e.g., signals reflected off an object) may be received by at least a portion of the ultrasonic sensor array at an acquisition time delay RGD and sampled during an acquisition time window RGW. Such acoustic waves may be generally be reflected from a portion of the target object the transmit beam is focused on (e.g., which may be a 2D surface, or a 3D portion, such as some subdermal layer). For example, in some cases, increasing the RGD may allow for imaging of subdermal features deeper in a finger. In some cases, range-gate delays may be integer multiples of a clock period. A clock frequency of 128 MHz, for example, may have a clock period of 7.8125 nanoseconds, and RGDs may range from under 10 nanoseconds to over 20,000 nanoseconds.

In some examples, a beam focused transmit wave may be received with or without receive side beamforming. In cases where transmit side beamforming may be utilized a power signal may be transmitted from each pixel. The sum of the signal from each pixel may be focused at the object. In cases where receive side beamforming may be implemented all of the reflected power signal may be captured at the receiver. In cases where no receive side beamforming may be implemented only power signal from certain elements may be captured at the receiver. In other examples, a plane transmit wave may be received with or without receive side beamforming. In other cases where no transmit side beamforming may be utilized a power signal may be transmitted from each pixel. The power signal from the pixels may be directed toward the object in the form of a plane wave with a power signal equal to a single pixel. In such cases where receive side beamforming may be implemented all of the reflected power signal may be captured at the receiver. In cases where no receive side beamforming may be implemented the power signal at the receiver may be less than the power signal directed toward the object. Receive side beamforming in addition to transmit side beam forming may provide a maximum signal to noise ratio.

In some examples, both transmit signal beamforming and receive signal beamforming methods may be utilized in a delay and sum beamforming technique. In such examples, transmit bursts and receive signal sampling may require separate delays. In some cases, delay channels may be reprogrammed between transmit signal burst and receive signal sampling.

Focusing in transmitting mode may be achieved by providing ultrasonic signal with a predefined delay to the different pixels within a super-pixel. These signals may be combined and may form a focused beam within the top imaging surface. In some cases, the transmit signal delay may be a function of several sensor architecture variables including diameter of the beam, aperture of the transmitting array, pitch of the transducer elements, the number of channels in a super-pixel, along with other mathematical constants Focusing in receiving mode may be achieved by sampling the returning ultrasonic signal with a predefined delay within the super-pixel. The received signals from all pixels in the super-pixel may be combined as a single readout. The readout may be capable of summing multiple rows and columns to perform receive beam forming in the hardware. In some cases, the receive signal delay may be a function several sensor architecture variables including diameter of the beam, aperture of the transmitting array, pitch of the transducer elements, the number of channels in a super-pixel, along with other mathematical constants

In some examples, there may be a number of methods for receive side beamforming with different readout architectures and beam forming models. Some methods may include a delay and sum beamforming technique. In some cases, the method may include receive signal (e.g., sampling. peak sampling, peak-to-peak sampling, peak sampling within a window, peak-to-peak sampling within a window, etc.) Other methods may include a peak detect and sum beamforming technique. In post-processing, receive signals may be calculated in a number of ways. One example may be by measuring the maximum absolute value of a receive signal in a max signal calculation. Another example may to measure the maximum value of a receive signal in a specific range in a peak to peak calculation. This method may avoid incorrect inference because of direct current (DC) offsets. In some cases, there may be a number of different receive signal sampling methods available for use in a beamforming model.

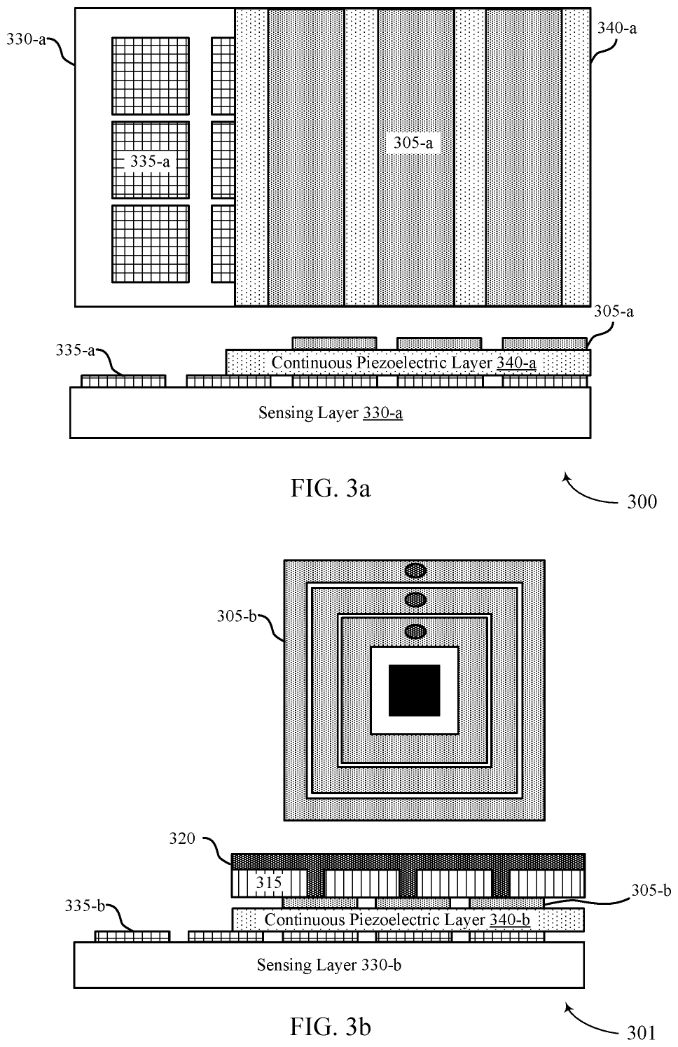

FIG. 3A illustrates an example of a sensor configuration 300 that supports ultrasonic biometric sensing with transmit and receive side beamforming in accordance with aspects of the present disclosure. In some examples, sensor configuration 300 may implement aspects of system 100 and/or system 101. In some cases, a sensor configuration 300 may be implemented under a display apparatus (e.g., cover glass, pOLED display, capacitive touch electrode, etc.). In some examples, sensor configuration 300 may comprise a sensing layer 330, a receive electrode array 335, a continuous piezoelectric layer 340, and column transmit electrodes 305 (e.g., a patterned top electrode making column transmit drivers). In the example of sensor configuration 300, transmit electrodes 305 may be patterned in a columnal fashion so as to enable 1D beamforming. Column transmit electrodes 305 may be able to drive and beamform transmit signals. A receive electrode array 335 may be able to receive incoming ultrasonic signals (e.g., signals reflected off an object). In some implementations, the sensing layer 330 may be a silicon substrate or a TFT substrate. Column transmit electrodes 305 and the receive electrode array 335 may be coupled to opposite surfaces of the piezoelectric layer 340.

In some cases, an ultrasonic signal may be transmitted by the column transmit electrodes 305 to focus the ultrasonic signal on an object. A portion of the wave not absorbed by the object to be detected may be reflected by the object and may pass back through a cover glass and the pOLED display (e.g., as described in more detail above, with reference to

FIG. 2). The reflected signal or the reflected wave may then be received by the receive electrode array 335. For example, the column transmit electrodes 305-a, 305-b, and 305-c may be individually driven by transmit signals with adjustable time delays to focus an ultrasonic signal. The receive electrode array 335 may then be used to scan signals reflected from an object.

FIG. 3B illustrates an example of a sensor configuration 301 that supports ultrasonic biometric sensing with transmit and receive side beamforming in accordance with aspects of the present disclosure. In some examples, sensor configuration 301 may implement aspects of system 100 and/or system 101. In some examples, a sensor configuration 301 may comprise a sensing layer 330, a receive electrode array 335, a continuous piezoelectric layer 340, transmit electrodes 305, a patterned dielectric 315, and a patterned routing layer 320. In some cases, a transmit electrodes 305 may be patterned in a fashion so as to enable 2D beamforming. Transmit electrodes 305 may be able to drive and beamform transmit signals. A receive electrode array 335 may be able to receive incoming ultrasonic signals (e.g., reflected off an object). In some implementations, the sensing layer 330 may be a silicon substrate or a TFT substrate. The transmit electrodes 305 and the receive electrode array 335 may be coupled to opposite surfaces of the piezoelectric layer.

In some cases, an ultrasonic signal may be transmitted by the transmit electrodes 305 to focus the ultrasonic signal on an object. A portion of the wave not absorbed by the object to be detected may be reflected by the object and may pass back through a cover glass and the pOLED display (e.g., as described in more detail above, with reference to FIG. 2). The reflected signal or the reflected wave may then be received by the receive electrode array 335. For example, the transmit electrodes 305-d, 305-e, and 305-f may be individually driven by transmit signals with adjustable time delays to focus an ultrasonic signal. The receive electrode array 335 may then be used to scan signals reflected from an object.

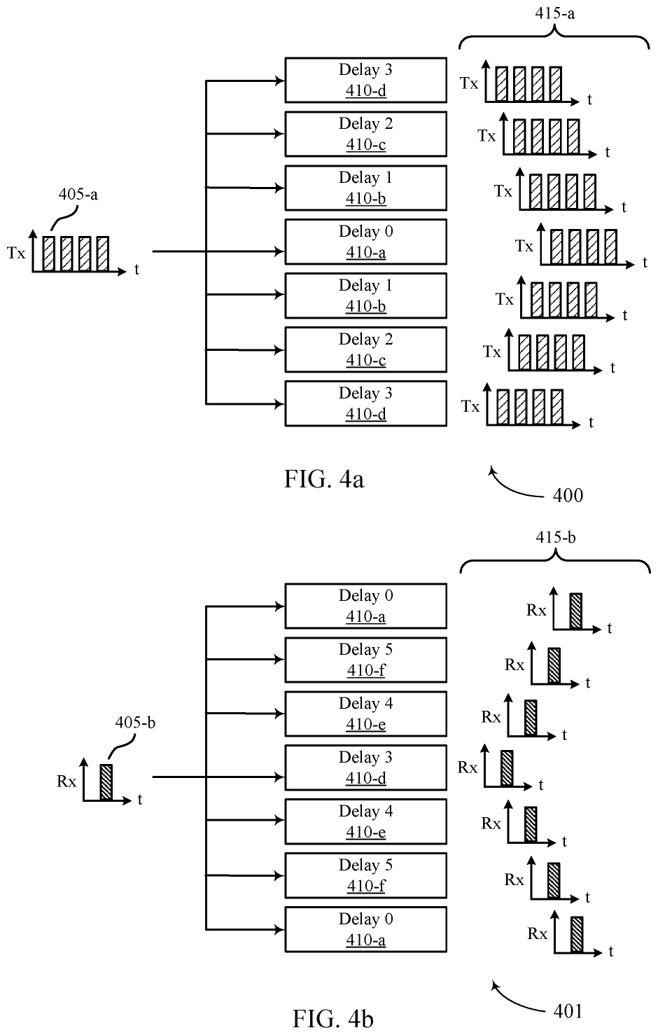

FIG. 4A illustrates an example of a transmit delay configuration 400 that supports ultrasonic biometric sensing with transmit and receive side beamforming in accordance with aspects of the present disclosure. In some examples, transmit delay configuration 400 (e.g., a transmit side channel delay distribution) may implement aspects of system 100 and/or system 101. In some cases, there may be a plurality of transmit signals 405 where each of the plurality of transmit signals has a different phase delay (e.g., delay channel 410) relative to other transmit signals of the plurality of transmit signals. In some cases, pairs of transmit signals may have the same delay (e.g., delay 0 410-a, delay 1 410-b, delay 2 410-c, delay 3 410-d, delay 4 410-e, delay 5 410-f) so as to form a symmetric transmission beam. In some cases, a transmit phase delay pattern 415-a may be symmetric about a focal point where the ultrasonic signal contacts an object. In other cases, an ultrasonic beam may be steered by using transmit phase delay patterns 415-a that may be asymmetric about a focal point where the ultrasonic signal contacts an object.

In some cases, a delay and sum beamforming technique may be implemented. In this case, the transmit phase delay pattern 415-a may be different from the receive sampling delay pattern 415-b. Transmit phase delay pattern 415-a and receive sampling delay pattern 415-b may support ultrasonic beamforming. In some examples, delay channels 410 may be reprogrammed between a transmit burst and a receive sampling mode. In some cases, transmit delay configuration 400 may illustrate transmit channel selection within a super-pixel.

As discussed above, pixels in a sensor architecture may be capable of transmit beam forming by selecting transmit channels (e.g., or groups of pixels/electrodes) with specific transmit delays to focus the transmit beam. For example, in some cases, a sensor may be capable of applying (e.g., driving or transmitting with) a limited number of time delays, and the number of channels may refer to how many time delays are implementable (e.g., how many transmit signals, with different time delays, may be driven by the electrode array). Transmit signals may be distributed in a super-pixel (e.g., for transmit beamforming). For example, a super-pixel array may include 10×10 grid of pixels (e.g., 100 total pixels), and may be assigned 7 different channels (e.g., the 100 pixels may be grouped into 7 channels). Each channel may be associated with a different time delay. In some cases, a transmit delay for a channel may be selected based on the portion of the object (e.g., the size of the portion, the location of the portion on the platen, etc.) as well as the properties of the sensor (e.g., the material properties of the copolymer, the thickness of the copolymer, the number of channels, etc.). In some cases, the number of channels may be selected (e.g., or the sensor may be designed to support a number of channels) based on the continuous piezoelectric layer (e.g., the copolymer). For example, in some cases, the number of channels may be selected based on the isolation properties of the continuous piezoelectric layer (e.g., copolymers with relatively high pixel isolation properties may support a higher number of channels, and thus more granular beamforming capabilities). Channels selected for transmission may depend on the configuration of the electrode array (e.g., copolymer properties, electrode array size, etc.), as well as the portion of the object to be imaged.

FIG. 4B illustrates an example of a receive delay configuration 401 that supports ultrasonic biometric sensing with transmit and receive side beamforming in accordance with aspects of the present disclosure. In some examples, receive delay configuration 401 (e.g., a receive side channel delay distribution) may implement aspects of system 100 and/or system 101. In some cases, there may be a plurality of receive signals 420 (e.g., signals reflected from an object) where each of the plurality of receive signals has a different phase delay (e.g., phase delay channels 410) relative to other receive signals of the plurality of receive signals. In some cases, some pairs of receive signals 420 may have the same delay (e.g., delay 0 410-a, delay 1 410-b, delay 2 410-c, delay 3 410-d, delay 4 410-e, delay 5 410-f) so as to form a symmetric receive sampling beam. In some cases, a receive sampling delay pattern 415-b may be symmetric about a focal point where the ultrasonic signal contacted an object. In other cases, an ultrasonic beam may be steered by using receive sampling delay patterns 415-b that are asymmetric about a focal point where the ultrasonic signal contacts an object.

In some cases, a delay and sum beamforming technique may be implemented. In this case, the transmit phase delay pattern 415-a may be different from the receive sampling delay pattern 415-b. Transmit phase delay pattern 415-a and receive sampling delay pattern 415-b may support ultrasonic beamforming. In some examples, delay channels 410 may be reprogrammed between a transmit burst and a receive sampling mode. In some cases, receive delay configuration 401 may illustrate receive channel selection (e.g., RGD selection) within a super-pixel. In some cases, delays of receive delay configuration 401 may be determined or identified based on delays of transmit delay configuration 400 (e.g., the ultrasonic signal transmission delay for each electrode of a sensor may be correlated with the one or more time delays for receiving signals or wave reflected from an object).

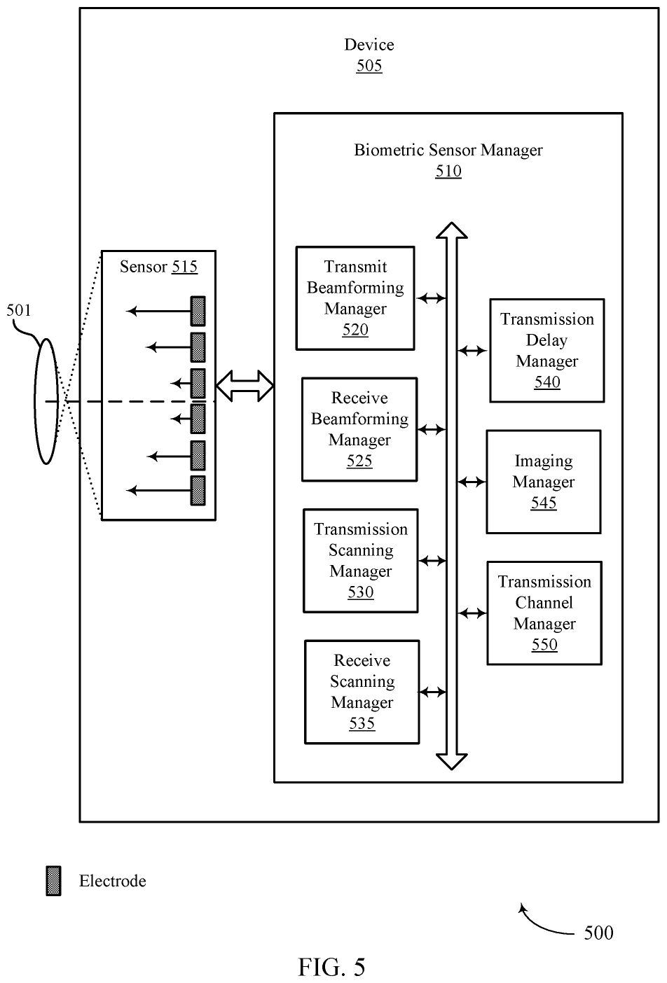

FIG. 5 shows a block diagram 500 of a device 505 that supports ultrasonic biometric sensing with transmit and receive side beamforming in accordance with aspects of the present disclosure. The device 505 may be an example of aspects of a device as described herein. The device 505 may include a biometric sensor manager 510 and a sensor 515. The device 505 may also include a processor. Each of these components may be in communication with one another (e.g., via one or more buses).

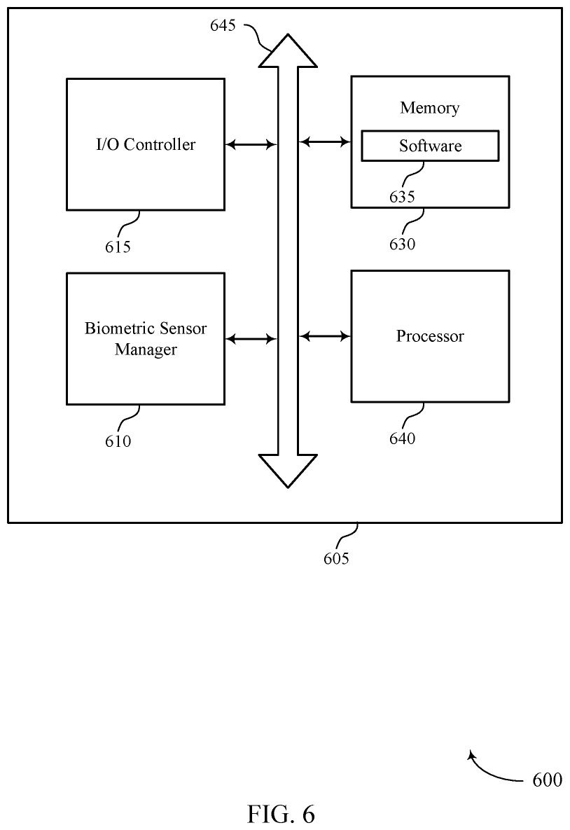

The sensor 515 may receive information such as packets, user data, or control information associated with various information channels (e.g., control channels, data channels, and information related to ultrasonic biometric sensing with transmit and receive side beamforming, etc.). Information may be passed on to other components of the device 505. The sensor 515 may be an example of aspects of the sensor architecture 200 and/or sensor configuration 300 described with reference to FIGS. 2 and 3. In some cases, the sensor 515 may be an example of aspects of the input/output (I/O) controller 615 as described with reference to FIG. 6.

The biometric sensor manager 510 may identify, for each of one or more electrodes of an electrode array, an ultrasonic signal transmission delay. The biometric sensor manager 510 may configure sensor 515 to transmit, based on a continuous piezoelectric layer, a beamformed ultrasonic signal based on the ultrasonic signal transmission delay for each of the one or more electrodes. The beamformed ultrasonic signal may be focused on a portion of an object. The biometric sensor manager 510 may then configure the sensor 515 to receive, using the electrode array, a reflected wave based on the transmitted beamformed ultrasonic signal. The biometric sensor manager 510 may then image the portion of the object based on the reflected wave. The biometric sensor manager 510 may be an example of aspects of the biometric sensor manager 610 described herein.

Device 505 may include a continuous (e.g., non-segmented) blanket layer of piezo-sensitive material (e.g., such as a continuous copolymer) between a common electrode and an electrode array. The electrode array may employ individual transmission cycle control for each electrode to perform aspects of ultrasonic transmit and receive beamforming for biometric sensing/imaging. That is, the electrode array may include several electrodes that may each be associated with (e.g., connected to) a transmit circuit and a receive circuit, where delays may be applied to each electrode or to selected groups of electrodes for transmit and receive beamforming. The sensor 515 may pass a signal representative of object imaging information to biometric sensor manager 510. The biometric sensor manager 510 may process such information to image the object, perform authentication procedures, etc. In some cases, the biometric sensor manager 510 and/or sensor 515 may introduce an applied voltage that may drive one or more electrodes of the sensor 515 to transmit a focused ultrasonic signal 501 (e.g., to focus a beam onto a point or portion of object). In some other cases, the biometric sensor manager 510 and/or sensor 515 may apply bias voltages to one or more electrodes of the sensor 515 to receive a signal reflected off an object.

The biometric sensor manager 510, or its sub-components, may be implemented in hardware, code (e.g., software or firmware) executed by a processor, or any combination thereof. If implemented in code executed by a processor, the functions of the biometric sensor manager 510, or its sub-components may be executed by a general-purpose processor, a DSP, an application-specific integrated circuit (ASIC), a FPGA or other programmable logic device, discrete gate or transistor logic, discrete hardware components, or any combination thereof designed to perform the functions described in the present disclosure.

The biometric sensor manager 510, or its sub-components, may be physically located at various positions, including being distributed such that portions of functions are implemented at different physical locations by one or more physical components. In some examples, the biometric sensor manager 510, or its sub-components, may be a separate and distinct component in accordance with various aspects of the present disclosure. In some examples, the biometric sensor manager 510, or its sub-components, may be combined with one or more other hardware components, including but not limited to an I/O component, a transceiver, a network server, another computing device, one or more other components described in the present disclosure, or a combination thereof in accordance with various aspects of the present disclosure.

The biometric sensor manager 510 may be an example of aspects of a biometric sensor manager 610 described herein. In some cases, the biometric sensor manager 510 may include a transmission delay manager 540, a transmit beamforming manager 520, a receive beamforming manager 525, an imaging manager 545, a transmission channel manager 550, a transmission scanning manager 530, and a receive scanning manager 535. Each of these modules may communicate, directly or indirectly, with one another (e.g., via one or more buses).

The transmission delay manager 540 may identify, for each of one or more electrodes of an electrode array, an ultrasonic signal transmission delay. In some examples, the transmission delay manager 540 may identify the ultrasonic signal transmission delay for each of the one or more electrodes based on the identified transmission channel, where the beamformed ultrasonic signal is transmitted based on the identified transmission channel and the identified ultrasonic signal transmission delay for each of the one or more electrodes. In some examples, the transmission delay manager 540 may vary the ultrasonic signal transmission delay for each of the one or more electrodes to focus the beamformed ultrasonic signal at various depths of the object.

The transmit beamforming manager 520 may transmit, based on a continuous piezoelectric layer, a beamformed ultrasonic signal based on the ultrasonic signal transmission delay for each of the one or more electrodes, where the beamformed ultrasonic signal is focused on a portion of an object. In some cases, the continuous piezoelectric layer includes a single continuous copolymer between the electrode array and a common electrode.

The receive beamforming manager 525 may receive, using the electrode array, a reflected wave based on the transmitted beamformed ultrasonic signal. In some examples, the receive beamforming manager 525 may sample the one or more reflected waves based on the receive beam. In some examples, the receive beamforming manager 525 may scan the receive beam portion by portion to image the object.

The imaging manager 545 may image the portion of the object based on the reflected wave. In some examples, the imaging manager 545 may image each scanned portion of the object. In some examples, the imaging manager 545 may combine each imaged portion of the object. In some examples, the imaging manager 545 may image the object based on the combining. In some examples, the imaging manager 545 may combine the results of the scanning to image the object. In some examples, the imaging manager 545 may sum rows of the object scanned with the receive beam. In some examples, the imaging manager 545 may sum columns of the object scanned with the receive beam.

The transmission channel manager 550 may identify a transmission channel based on the continuous piezoelectric layer and the electrode array. In some examples, the transmission channel manager 550 may identify one or more transmission channels based on the electrode array and a number of ultrasonic transmission delays for transmitting the beamformed ultrasonic signal. In some examples, the transmission channel manager 550 may select a transmission channel of the one or more transmission channels based on the portion of the object, where the beamformed ultrasonic signal is transmitted based on the selected transmission channel.

The transmission scanning manager 530 may scan the beamformed ultrasonic signal portion by portion across the object.

The receive scanning manager 535 may identify a receive beam using, for each of the one or more electrodes of an electrode array, a time delay for receiving one or more reflected waves based on the scanning. In some cases, the ultrasonic signal transmission delay for each of the one or more electrodes are correlated with the one or more time delays for receiving the one or more reflected waves.

FIG. 6 shows a diagram of a system 600 including a device 605 that supports ultrasonic biometric sensing with transmit and receive side beamforming in accordance with aspects of the present disclosure. The device 605 may be an example of or include the components of device 505, or a device 105 as described herein. The device 605 may include components for bi-directional voice and data communications including components for transmitting and receiving communications, including a biometric sensor manager 610, an I/O controller 615, memory 630, and a processor 640. These components may be in electronic communication via one or more buses (e.g., bus 645).

The biometric sensor manager 610 may identify, for each of one or more electrodes of an electrode array, an ultrasonic signal transmission delay, transmit, based on a continuous piezoelectric layer, a beamformed ultrasonic signal based on the ultrasonic signal transmission delay for each of the one or more electrodes, where the beamformed ultrasonic signal is focused on a portion of an object, receive, using the electrode array, a reflected wave based on the transmitted beamformed ultrasonic signal, and image the portion of the object based on the reflected wave.

The I/O controller 615 may manage input and output signals for the device 605. The I/O controller 615 may also manage peripherals not integrated into the device 605. In some cases, the I/O controller 615 may represent a physical connection or port to an external peripheral. In some cases, the I/O controller 615 may utilize an operating system such as iOS®, ANDROID®, MS-DOS®, MS-WINDOWS®, OS/2®, UNIX®, LINUX®, or another known operating system. In other cases, the I/O controller 615 may represent or interact with a modem, a keyboard, a mouse, a touchscreen, or a similar device. In some cases, the I/O controller 615 may be implemented as part of a processor. In some cases, a user may interact with the device 605 via the I/O controller 615 or via hardware components controlled by the I/O controller 615.

The memory 630 may include RAM and ROM. The memory 630 may store computer-readable, computer-executable code or software 635 including instructions that, when executed, cause the processor to perform various functions described herein. In some cases, the memory 630 may contain, among other things, a BIOS which may control basic hardware or software operation such as the interaction with peripheral components or devices.

The processor 640 may include an intelligent hardware device, (e.g., a general-purpose processor, a DSP, a CPU, a microcontroller, an ASIC, an FPGA, a programmable logic device, a discrete gate or transistor logic component, a discrete hardware component, or any combination thereof). In some cases, the processor 640 may be configured to operate a memory array using a memory controller. In other cases, a memory controller may be integrated into the processor 640. The processor 640 may be configured to execute computer-readable instructions stored in a memory (e.g., the memory 630) to cause the device 605 to perform various functions (e.g., functions or tasks supporting ultrasonic biometric sensing with transmit and receive side beamforming).

The software 635 may include instructions to implement aspects of the present disclosure, including instructions to support biometric scanning. The software 635 may be stored in a non-transitory computer-readable medium such as system memory or other type of memory. In some cases, the software 635 may not be directly executable by the processor 640 but may cause a computer (e.g., when compiled and executed) to perform functions described herein.

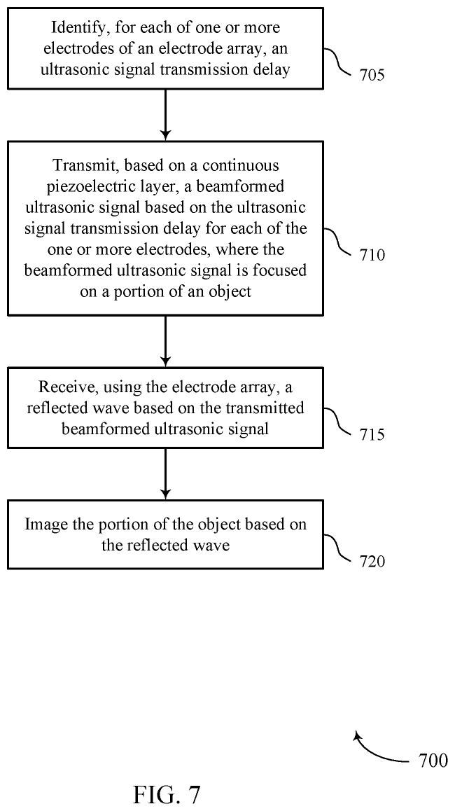

FIG. 7 shows a flowchart illustrating a method 700 that supports ultrasonic biometric sensing with transmit and receive side beamforming in accordance with aspects of the present disclosure. The operations of method 700 may be implemented by a device or its components as described herein. For example, the operations of method 700 may be performed by a biometric sensor manager as described with reference to FIGS. 5 and 6. In some examples, a device may execute a set of instructions to control the functional elements of the device to perform the functions described below. Additionally or alternatively, a device may perform aspects of the functions described below using special-purpose hardware.

At 705, the device may identify, for each of one or more electrodes of an electrode array, an ultrasonic signal transmission delay. The operations of 705 may be performed according to the methods described herein. In some examples, aspects of the operations of 705 may be performed by a transmission delay manager as described with reference to FIGS. 5 and 6.

At 710, the device may transmit, based on a continuous piezoelectric layer, a beamformed ultrasonic signal based on the ultrasonic signal transmission delay for each of the one or more electrodes, where the beamformed ultrasonic signal is focused on a portion of an object. The operations of 710 may be performed according to the methods described herein. In some examples, aspects of the operations of 710 may be performed by a transmit beamforming manager as described with reference to FIGS. 5 and 6.

At 715, the device may receive, using the electrode array, a reflected wave based on the transmitted beamformed ultrasonic signal. The operations of 715 may be performed according to the methods described herein. In some examples, aspects of the operations of 715 may be performed by a receive beamforming manager as described with reference to FIGS. 5 and 6.

At 720, the device may image the portion of the object based on the reflected wave. The operations of 720 may be performed according to the methods described herein. In some examples, aspects of the operations of 720 may be performed by an imaging manager as described with reference to FIGS. 5 and 6.

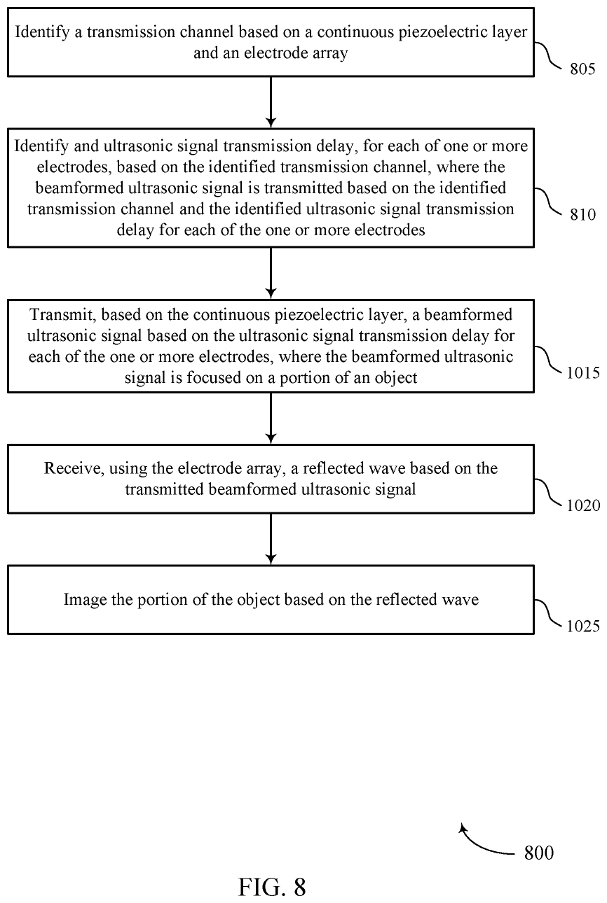

FIG. 8 shows a flowchart illustrating a method 800 that supports ultrasonic biometric sensing with transmit and receive side beamforming in accordance with aspects of the present disclosure. The operations of method 800 may be implemented by a device or its components as described herein. For example, the operations of method 800 may be performed by a biometric sensor manager as described with reference to FIGS. 5 and 6. In some examples, a device may execute a set of instructions to control the functional elements of the device to perform the functions described below. Additionally or alternatively, a device may perform aspects of the functions described below using special-purpose hardware.

At 805, the device may identify a transmission channel based on a continuous piezoelectric layer and an electrode array. The operations of 805 may be performed according to the methods described herein. In some examples, aspects of the operations of 805 may be performed by a transmission channel manager as described with reference to FIGS. 5 and 6.

At 810, the device may identify an ultrasonic signal transmission delay, for each of one or more electrodes (e.g., of the electrode array), based on the identified transmission channel, where the beamformed ultrasonic signal is transmitted based on the identified transmission channel and the identified ultrasonic signal transmission delay for each of the one or more electrodes. The operations of 810 may be performed according to the methods described herein. In some examples, aspects of the operations of 810 may be performed by a transmission delay manager as described with reference to FIGS. 5 and 6.

At 815, the device may transmit, based on the continuous piezoelectric layer, a beamformed ultrasonic signal based on the ultrasonic signal transmission delay for each of the one or more electrodes, where the beamformed ultrasonic signal is focused on a portion of an object. The operations of 815 may be performed according to the methods described herein. In some examples, aspects of the operations of 815 may be performed by a transmit beamforming manager as described with reference to FIGS. 5 and 6.

At 820, the device may receive, using the electrode array, a reflected wave based on the transmitted beamformed ultrasonic signal. The operations of 820 may be performed according to the methods described herein. In some examples, aspects of the operations of 820 may be performed by a receive beamforming manager as described with reference to FIGS. 5 and 6.

At 825, the device may image the portion of the object based on the reflected wave. The operations of 825 may be performed according to the methods described herein. In some examples, aspects of the operations of 825 may be performed by an imaging manager as described with reference to FIGS. 5 and 6.

It should be noted that the methods described herein describe possible implementations, and that the operations and the steps may be rearranged or otherwise modified and that other implementations are possible. Further, aspects from two or more of the methods may be combined.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and modules described in connection with the disclosure herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The functions described herein may be implemented in hardware, software executed by a processor, firmware, or any combination thereof If implemented in software executed by a processor, the functions may be stored on or transmitted over as one or more instructions or code on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media may include random-access memory (RAM), read-only memory (ROM), electrically erasable programmable ROM (EEPROM), flash memory, compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

As used herein, including in the claims, “or” as used in a list of items (e.g., a list of items prefaced by a phrase such as “at least one of” or “one or more of”) indicates an inclusive list such that, for example, a list of at least one of A, B, or C means A or B or C or AB or AC or BC or ABC (e.g., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label, or other subsequent reference label.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, well-known structures and devices are shown in block diagram form in order to avoid obscuring the concepts of the described examples.

The description herein is provided to enable a person skilled in the art to make or use the disclosure. Various modifications to the disclosure will be readily apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A method for biometric scanning at a device, comprising:
identifying, for each of one or more electrodes of an electrode array, an ultrasonic signal transmission delay;
transmitting, based at least in part on a continuous piezoelectric layer, a beamformed ultrasonic signal based at least in part on the ultrasonic signal transmission delay for each of the one or more electrodes, wherein the beamformed ultrasonic signal is focused on a portion of an object;
receiving, using the electrode array, a reflected wave based at least in part on the transmitted beamformed ultrasonic signal; and
imaging the portion of the object based at least in part on the reflected wave.

2. The method of claim 1, further comprising:
identifying a transmission channel based at least in part on the continuous piezoelectric layer and the electrode array; and
identifying the ultrasonic signal transmission delay for each of the one or more electrodes based at least in part on the identified transmission channel, wherein the beamformed ultrasonic signal is transmitted based at least in part on the identified transmission channel and the identified ultrasonic signal transmission delay for each of the one or more electrodes.

3. The method of claim 1, wherein the continuous piezoelectric layer comprises a single continuous copolymer between the electrode array and a common electrode.

4. The method of claim 1, further comprising:
scanning the beamformed ultrasonic signal portion by portion across the object;
imaging each scanned portion of the object;
combining each imaged portion of the object; and
imaging the object based at least in part on the combining.

5. The method of claim 1, further comprising:
scanning the beamformed ultrasonic signal portion by portion across the object;
identifying a receive beam using, for each of the one or more electrodes of the electrode array, a time delay for receiving one or more reflected waves based at least in part on the scanning; and
sampling the one or more reflected waves based at least in part on the receive beam.

6. The method of claim 5, further comprising:
scanning the receive beam portion by portion to image the object; and
combining the results of the scanning to image the object.

7. The method of claim 6, wherein combining the results of the scanning comprises:
summing rows of the object scanned with the receive beam; and
summing columns of the object scanned with the receive beam.

8. The method of claim 5, wherein the ultrasonic signal transmission delay for each of the one or more electrodes are correlated with the one or more time delays for receiving the one or more reflected waves.

9. The method of claim 1, further comprising:
varying the ultrasonic signal transmission delay for each of the one or more electrodes to focus the beamformed ultrasonic signal at various depths of the object.

10. The method of claim 1, further comprising:
identifying one or more transmission channels based at least in part on the electrode array and a number of ultrasonic transmission delays for transmitting the beamformed ultrasonic signal; and
selecting a transmission channel of the one or more transmission channels based at least in part on the portion of the object, wherein the beamformed ultrasonic signal is transmitted based at least in part on the selected transmission channel.

11. An apparatus for biometric scanning at a device, comprising:
a processor,
memory in electronic communication with the processor; and
instructions stored in the memory and executable by the processor to cause the apparatus to:
identify, for each of one or more electrodes of an electrode array, an ultrasonic signal transmission delay;
transmit, based at least in part on a continuous piezoelectric layer, a beamformed ultrasonic signal based at least in part on the ultrasonic signal transmission delay for each of the one or more electrodes, wherein the beamformed ultrasonic signal is focused on a portion of an object;
receive, using the electrode array, a reflected wave based at least in part on the transmitted beamformed ultrasonic signal; and
image the portion of the object based at least in part on the reflected wave.

12. The apparatus of claim 11, wherein the instructions are further executable by the processor to cause the apparatus to:
identify a transmission channel based at least in part on the continuous piezoelectric layer and the electrode array; and
identify the ultrasonic signal transmission delay for each of the one or more electrodes based at least in part on the identified transmission channel, wherein the beamformed ultrasonic signal is transmitted based at least in part on the identified transmission channel and the identified ultrasonic signal transmission delay for each of the one or more electrodes.

13. The apparatus of claim 11, wherein the continuous piezoelectric layer comprises a single continuous copolymer between the electrode array and a common electrode.

14. The apparatus of claim 11, wherein the instructions are further executable by the processor to cause the apparatus to:
scan the beamformed ultrasonic signal portion by portion across the object;
image each scanned portion of the object;
combine each imaged portion of the object; and
image the object based at least in part on the combining.

15. The apparatus of claim 11, wherein the instructions are further executable by the processor to cause the apparatus to:
scan the beamformed ultrasonic signal portion by portion across the object;
identify a receive beam using, for each of the one or more electrodes of the electrode array, a time delay for receiving one or more reflected waves based at least in part on the scanning; and
sample the one or more reflected waves based at least in part on the receive beam.

16. The apparatus of claim 15, wherein the instructions are further executable by the processor to cause the apparatus to:
scan the receive beam portion by portion to image the object; and
combine the results of the scanning to image the object.

17. The apparatus of claim 16, wherein the instructions to combine the results of the scanning are executable by the processor to cause the apparatus to:
sum rows of the object scanned with the receive beam; and
sum columns of the object scanned with the receive beam.

18. The apparatus of claim 15, wherein the ultrasonic signal transmission delay for each of the one or more electrodes are correlated with the one or more time delays for receiving the one or more reflected waves.

19. The apparatus of claim 11, wherein the instructions are further executable by the processor to cause the apparatus to:
vary the ultrasonic signal transmission delay for each of the one or more electrodes to focus the beamformed ultrasonic signal at various depths of the object.

20. An apparatus for biometric scanning at a device, comprising:
means for identifying, for each of one or more electrodes of an electrode array, an ultrasonic signal transmission delay;
means for transmitting, based at least in part on a continuous piezoelectric layer, a beamformed ultrasonic signal based at least in part on the ultrasonic signal transmission delay for each of the one or more electrodes, wherein the beamformed ultrasonic signal is focused on a portion of an object;
means for receiving, using the electrode array, a reflected wave based at least in part on the transmitted beamformed ultrasonic signal; and
means for imaging the portion of the object based at least in part on the reflected wave.
